(19) United States
(12) Patent Application Publication
(10) Pub. No.: US 2025/0020941 A1
(43) Pub. Date: Jan. 16, 2025

(54) Electronic Device Displays with Lenses and Color Filters

(71) Applicant: Apple Inc., Cupertino, CA (US)

(72) Inventors: Hao Chen, Santa Clara, CA (US); ByoungSuk Kim, Palo Alto, CA (US); Fu-Chung Huang, Cupertino, CA (US); Juan He, San Jose, CA (US); Jun Qi, San Jose, CA (US); Ping-Yen Chou, Santa Clara, CA (US); Yi Huang, San Jose, CA (US); Yi-Pai Huang, Zhubei (TW)

(21) Appl. No.: 18/737,653

(22) Filed: Jun. 7, 2024

Related U.S. Application Data
(60) Provisional application No. 63/513,173, filed on Jul. 12, 2023.

(51) Int. Cl. G02B 30/29; G02B 3/00; G02B 3/08; G02B 5/20; H01L 27/15

(52) U.S. Cl. CPC G02B 30/29; G02B 3/0043; G02B 3/005; G02B 3/0056; G02B 3/08; G02B 5/201; H01L 27/156

(57) ABSTRACT

An electronic device may include a stereoscopic display that is configured to display three-dimensional content for a viewer. The stereoscopic display may include a lenticular lens film with lenticular lenses that extend across the length of the display and may be referred to as a lenticular display. The lenticular display may have convex curvature. The lenticular display may include a color filter layer with color filters and an opaque masking layer. The color filter layer may be interposed between the lenticular lens film and an array of display pixels for the display. The color filter layer may mitigate ghost image artifacts and reflections of ambient light. Microlenses may be included between the lenticular lens film and the array of display pixels to improve the efficiency of the display. The display may include a Fresnel lens layer. The lenticular lens film may include lenticular lenses having different shapes.

This application claims the benefit of U.S. provisional patent application No. 63/513,173, filed Jul. 12, 2023, which is hereby incorporated by reference herein in its entirety.

### FIELD

This relates generally to electronic devices, and, more particularly, to electronic devices with displays.

### BACKGROUND

Electronic devices often include displays. In some cases, displays may include lenticular lenses that enable the display to provide three-dimensional content to the viewer. The lenticular lenses may be formed over an array of pixels such as organic light-emitting diode pixels or liquid crystal display pixels.

If care is not taken, it may be difficult to provide lenticular displays with desired form factors. Lenticular displays may also be susceptible to crosstalk and other visible artifacts at wide viewing angles.

### SUMMARY

An electronic device may include a display. The display may include a substrate, an array of pixels formed on the substrate that includes red pixels, green pixels, and blue pixels, a lenticular lens film formed over the array of pixels, and a color filter layer that is interposed between the array of pixels and the lenticular lens film. The color filter layer may include an opaque masking layer that defines openings for color filters and the color filters may include red color filters that are aligned with the red pixels, green color filters that are aligned with the green pixels, and blue color filters that are aligned with the blue pixels.

An electronic device may include a display. The display may include a substrate having first and second opposing surfaces, the first surface having convex curvature, an array of pixels that conforms to the first surface and has the convex curvature, a lenticular lens film formed over the array of pixels, a color filter layer that is interposed between the array of pixels and the lenticular lens film and that includes color filters and an opaque masking layer between the color filters, and a Fresnel lens layer that is formed over the lenticular lens film and that redirects light from the array of pixels by different amounts at different positions across the display.

An electronic device may include a display. The display may include a substrate having first and second opposing surfaces, the first surface having convex curvature, an array of pixels that conforms to the first surface and has the convex curvature, a lenticular lens film formed over the array of pixels, and a color filter layer that is interposed between the array of pixels and the lenticular lens film. The color filter layer may include color filters and an opaque masking layer between the color filters, a first color filter in a center of the display may overlap a first pixel in a first direction, a second color filter in an edge the display may overlap a second pixel in the first direction, the first color filter may have a first center, the first pixel may have a second center, the second color filter may have a third center, the second pixel may have a fourth center, the first center may be aligned with the second center in the first direction, and the third center may be shifted relative to the fourth center in a direction that is parallel to a plane defined by the substrate at a portion of the substrate that supports the second pixel.

### BRIEF DESCRIPTION OF THE DRAWINGS

FIG. 1 is a schematic diagram of an illustrative electronic device having a display in accordance with some embodiments.

FIG. 2 is a top view of an illustrative display in an electronic device in accordance with some embodiments.

FIG. 3 is a side view of an illustrative lenticular display that provides images to a viewer in accordance with some embodiments.

FIG. 4 is a side view of an illustrative lenticular display that provides images to two or more viewers in accordance with some embodiments.

FIG. 5 is a top view of an illustrative lenticular lens film showing the elongated shape of the lenticular lenses in accordance with some embodiments.

FIG. 6 is a side view of an illustrative lenticular display with a color filter layer between a display panel and a lenticular lens film in accordance with some embodiments.

FIG. 7A is a side view of an illustrative lenticular display with microlenses interposed between a color filter layer and a display panel in accordance with some embodiments.

FIG. 7B is a side view of an illustrative lenticular display with microlenses interposed between a color filter layer and a lenticular lens film in accordance with some embodiments.

FIGS. 8 and 9 are side views of an illustrative lenticular display with convex curvature and a Fresnel lens layer in accordance with some embodiments.

FIG. 10A is a side view of an illustrative lenticular lens film for a display with convex curvature showing a lenticular lens having a symmetric shape in a center of the display in accordance with some embodiments.

FIG. 10B is a side view of the illustrative lenticular lens film of FIG. 10A showing a lenticular lens having an asymmetric shape in an edge of the display in accordance with some embodiments.

FIG. 11 is a graph of deflection as a function of position for the Fresnel lens layer of FIGS. 8 and 9 and the lenticular lens film of FIGS. 10A and 10B in accordance with some embodiments.

FIG. 12 is a side view of an illustrative lenticular display with color filters and microlenses that are laterally shifted in accordance with some embodiments.

FIG. 13 is a graph of lateral shift as a function of position for the color filters and microlenses of FIG. 12 in accordance with some embodiments.

### DETAILED DESCRIPTION

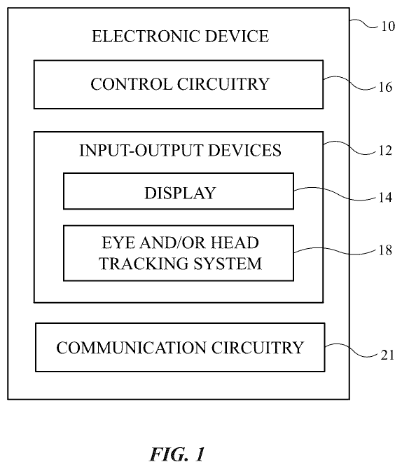

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, an augmented reality (AR) headset and/or virtual reality (VR) headset, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

To support communications between device 10 and external equipment, control circuitry 16 may communicate using communications circuitry 21. Circuitry 21 may include antennas, radio-frequency transceiver circuitry, and other wireless communications circuitry and/or wired communications circuitry. Circuitry 21, which may sometimes be referred to as control circuitry and/or control and communications circuitry, may support bidirectional wireless communications between device 10 and external equipment over a wireless link (e.g., circuitry 21 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a 60 GHz link or other millimeter wave link, a cellular telephone link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, and other electrical components. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Some electronic devices may include two displays. In one possible arrangement, a first display may be positioned on one side of the device and a second display may be positioned on a second, opposing side of the device. The first and second displays therefore may have a back-to-back arrangement. One or both of the displays may be curved.

Sensors in input-output devices 12 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors in input-output devices 12 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors.

Control circuitry 16 may be used to run software on device 10 such as operating system code and applications. During operation of device 10, the software running on control circuitry 16 may display images on display 14 using an array of pixels in display 14.

Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display are sometimes described herein as an example.

Display 14 may have a rectangular shape (i.e., display 14 may have a rectangular footprint and a rectangular peripheral edge that runs around the rectangular footprint) or may have other suitable shapes. Display 14 may be planar or may have a curved profile.

Device 10 may include cameras and other components that form part of gaze and/or head tracking system 18. The camera(s) or other components of system 18 may face a user's eyes and may track the user's eyes and/or head (e.g., images and other information captured by system 18 may be analyzed by control circuitry 16 to determine the location of the user's eyes and/or head). This eye-location information obtained by system 18 may be used to determine the appropriate direction with which display content from display 14 should be directed. If desired, image sensors other than cameras (e.g., infrared and/or visible light-emitting diodes and light detectors, etc.) may be used in system 18 to monitor a user's eye and/or head location.

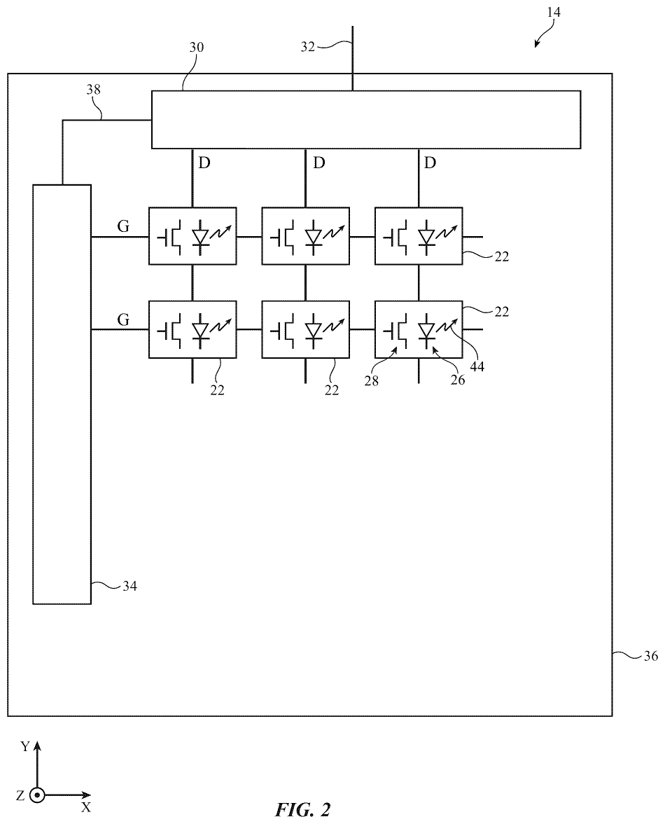

A top view of a portion of display 14 is shown in FIG. 2. As shown in FIG. 2, display 14 may have an array of pixels 22 formed on substrate 36. Substrate 36 may be formed from glass, metal, plastic, ceramic, or other substrate materials. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may have a light-emitting diode 26 that emits light 24 under the control of a pixel circuit formed from thin-film transistor circuitry (such as thin-film transistors 28 and thin-film capacitors). Thin-film transistors 28 may be polysilicon thin-film transistors, semiconducting-oxide thin-film transistors such as indium gallium zinc oxide transistors, or thin-film transistors formed from other semiconductors. Pixels 22 may contain light-emitting diodes of different colors (e.g., red, green, and blue diodes for red, green, and blue pixels, respectively) to provide display 14 with the ability to display color images.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, circuitry 30 may also supply clock signals and other control signals to gate driver circuitry on an opposing edge of display 14.

Gate driver circuitry 34 (sometimes referred to as horizontal control line control circuitry) may be implemented as part of an integrated circuit and/or may be implemented using thin-film transistor circuitry. Horizontal control lines G in display 14 may carry gate line signals (scan line signals), emission enable control signals, and other horizontal control signals for controlling the pixels of each row. There may be any suitable number of horizontal control signals per row of pixels 22 (e.g., one or more, two or more, three or more, four or more, etc.).

Display 14 may sometimes be a stereoscopic display that is configured to display three-dimensional content for a viewer. Stereoscopic displays are capable of displaying multiple two-dimensional images that are viewed from slightly different angles. When viewed together, the combination of the two-dimensional images creates the illusion of a three-dimensional image for the viewer. For example, a viewer's left eye may receive a first two-dimensional image and a viewer's right eye may receive a second, different two-dimensional image. The viewer perceives these two different two-dimensional images as a single three-dimensional image.

There are numerous ways to implement a stereoscopic display. Display 14 may be a lenticular display that uses lenticular lenses (e.g., elongated lenses that extend along parallel axes), may be a parallax barrier display that uses parallax barriers (e.g., an opaque layer with precisely spaced slits to create a sense of depth through parallax), may be a volumetric display, or may be any other desired type of stereoscopic display. Configurations in which display 14 is a lenticular display are sometimes described herein as an example.

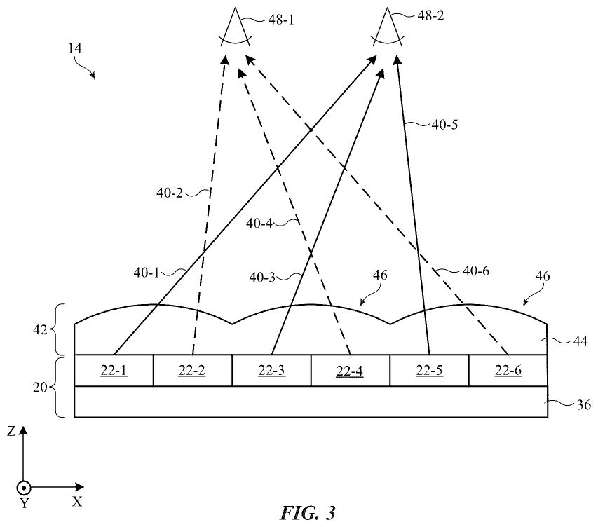

FIG. 3 is a cross-sectional side view of an illustrative lenticular display that may be incorporated into electronic device 10. Display 14 includes a display panel 20 with pixels 22 on substrate 36. Substrate 36 may be formed from glass, metal, plastic, ceramic, or other substrate materials and pixels 22 may be organic light-emitting diode pixels, liquid crystal display pixels, or any other desired type of pixels.

As shown in FIG. 3, lenticular lens film 42 may be formed over the display pixels. Lenticular lens film 42 (sometimes referred to as a light redirecting film, a lens film, etc.) includes lenses 46 and a base film portion 44 (e.g., a planar film portion to which lenses 46 are attached). Lenses 46 may be lenticular lenses that extend along respective longitudinal axes (e.g., axes that extend into the page parallel to the Y-axis). Lenses 46 may be referred to as lenticular elements 46, lenticular lenses 46, optical elements 46, etc.

The lenses 46 of the lenticular lens film cover the pixels of display 14. An example is shown in FIG. 3 with display pixels 22-1, 22-2, 22-3, 22-4, 22-5, and 22-6. In this example, display pixels 22-1 and 22-2 are covered by a first lenticular lens 46, display pixels 22-3 and 22-4 are covered by a second lenticular lens 46, and display pixels 22-5 and 22-6 are covered by a third lenticular lens 46. The lenticular lenses may redirect light from the display pixels to enable stereoscopic viewing of the display.

Consider the example of display 14 being viewed by a viewer with a first eye (e.g., a right eye) 48-1 and a second eye (e.g., a left eye) 48-2. Light from pixel 22-1 is directed by the lenticular lens film in direction 40-1 towards left eye 48-2, light from pixel 22-2 is directed by the lenticular lens film in direction 40-2 towards right eye 48-1, light from pixel 22-3 is directed by the lenticular lens film in direction 40-3 towards left eye 48-2, light from pixel 22-4 is directed by the lenticular lens film in direction 40-4 towards right eye 48-1, light from pixel 22-5 is directed by the lenticular lens film in direction 40-5 towards left eye 48-2, light from pixel 22-6 is directed by the lenticular lens film in direction 40-6 towards right eye 48-1. In this way, the viewer's right eye 48-1 receives images from pixels 22-2, 22-4, and 22-6, whereas left eye 48-2 receives images from pixels 22-1, 22-3, and 22-5. Pixels 22-2, 22-4, and 22-6 may be used to display a slightly different image than pixels 22-1, 22-3, and 22-5. Consequently, the viewer may perceive the received images as a single three-dimensional image.

Pixels of the same color may be covered by a respective lenticular lens 46. In one example, pixels 22-1 and 22-2 may be red pixels that emit red light, pixels 22-3 and 22-4 may be green pixels that emit green light, and pixels 22-5 and 22-6 may be blue pixels that emit blue light. This example is merely illustrative. In general, each lenticular lens may cover any desired number of pixels each having any desired color. The lenticular lens may cover a plurality of pixels having the same color, may cover a plurality of pixels each having different colors, may cover a plurality of pixels with some pixels being the same color and some pixels being different colors, etc.

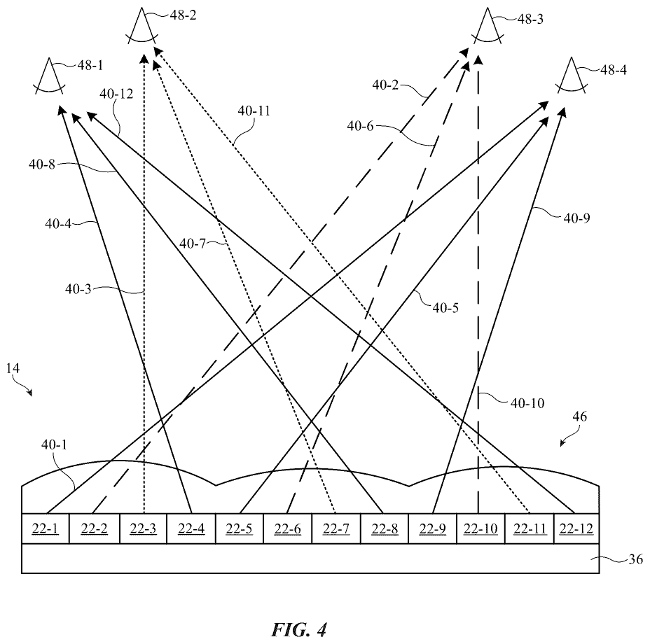

FIG. 4 is a cross-sectional side view of an illustrative stereoscopic display showing how the stereoscopic display may be viewable by multiple viewers. The stereoscopic display of FIG. 3 may have one optimal viewing position (e.g., one viewing position where the images from the display are perceived as three-dimensional). The stereoscopic display of FIG. 4 may have two optimal viewing positions (e.g., two viewing positions where the images from the display are perceived as three-dimensional).

Display 14 may be viewed by both a first viewer with a right eye 48-1 and a left eye 48-2 and a second viewer with a right eye 48-3 and a left eye 48-4. Light from pixel 22-1 is directed by the lenticular lens film in direction 40-1 towards left eye 48-4, light from pixel 22-2 is directed by the lenticular lens film in direction 40-2 towards right eye 48-3, light from pixel 22-3 is directed by the lenticular lens film in direction 40-3 towards left eye 48-2, light from pixel 22-4 is directed by the lenticular lens film in direction 40-4 towards right eye 48-1, light from pixel 22-5 is directed by the lenticular lens film in direction 40-5 towards left eye 48-4, light from pixel 22-6 is directed by the lenticular lens film in direction 40-6 towards right eye 48-3, light from pixel 22-7 is directed by the lenticular lens film in direction 40-7 towards left eye 48-2, light from pixel 22-8 is directed by the lenticular lens film in direction 40-8 towards right eye 48-1, light from pixel 22-9 is directed by the lenticular lens film in direction 40-9 towards left eye 48-4, light from pixel 22-10 is directed by the lenticular lens film in direction 40-10 towards right eye 48-3, light from pixel 22-11 is directed by the lenticular lens film in direction 40-11 towards left eye 48-2, and light from pixel 22-12 is directed by the lenticular lens film in direction 40-12 towards right eye 48-1. In this way, the first viewer's right eye 48-1 receives images from pixels 22-4, 22-8, and 22-12, whereas left eye 48-2 receives images from pixels 22-3, 22-7, and 22-11. Pixels 22-4, 22-8, and 22-12 may be used to display a slightly different image than pixels 22-3, 22-7, and 22-11. Consequently, the first viewer may perceive the received images as a single three-dimensional image. Similarly, the second viewer's right eye 48-3 receives images from pixels 22-2, 22-6, and 22-10, whereas left eye 48-4 receives images from pixels 22-1, 22-5, and 22-9. Pixels 22-2, 22-6, and 22-10 may be used to display a slightly different image than pixels 22-1, 22-5, and 22-9. Consequently, the second viewer may perceive the received images as a single three-dimensional image.

Pixels of the same color may be covered by a respective lenticular lens 46. In one example, pixels 22-1, 22-2, 22-3, and 22-4 may be red pixels that emit red light, pixels 22-5, 22-6, 22-7, and 22-8 may be green pixels that emit green light, and pixels 22-9, 22-10, 22-11, and 22-12 may be blue pixels that emit blue light. This example is merely illustrative. The display may be used to present the same three-dimensional image to both viewers or may present different three-dimensional images to different viewers. In some cases, control circuitry in the electronic device 10 may use eye and/or head tracking system 18 to track the position of one or more viewers and display content on the display based on the detected position of the one or more viewers.

It should be understood that the lenticular lens shapes and directional arrows of FIGS. 3 and 4 are merely illustrative. The actual rays of light from each pixel may follow more complicated paths (e.g., with redirection occurring due to refraction, total internal reflection, etc.). Additionally, light from each pixel may be emitted over a range of angles. The lenticular display may also have lenticular lenses of any desired shape or shapes. Each lenticular lens may have a width that covers two pixels, three pixels, four pixels, more than four pixels, more than ten pixels, etc. Each lenticular lens may have a length that extends across the entire display (e.g., parallel to columns of pixels in the display).

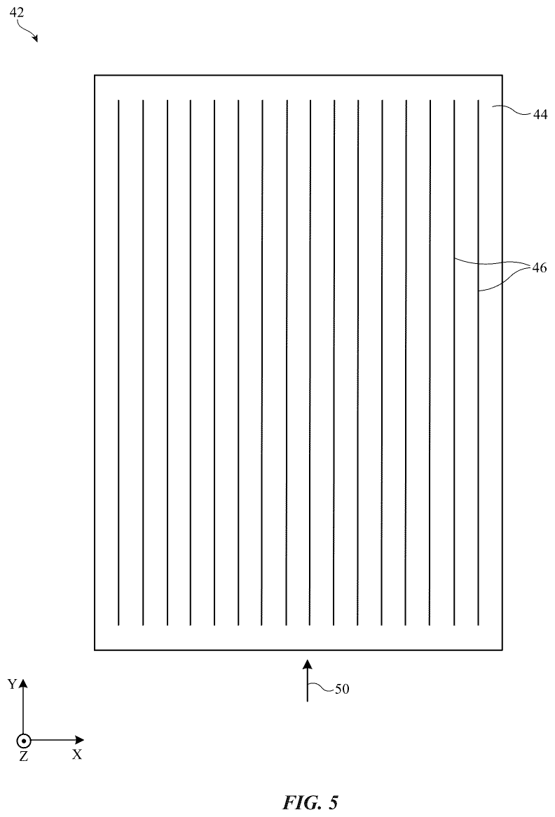

FIG. 5 is a top view of an illustrative lenticular lens film that may be incorporated into a lenticular display. As shown in FIG. 5, elongated lenses 46 extend across the display parallel to the Y-axis. The lenticular lenses have curvature along the X-direction and spread light in the X-direction. For example, the cross-sectional side view of FIGS. 3 and 4 may be taken looking in direction 50. The lenticular display may include any desired number of lenticular lenses 46 (e.g., more than 10, more than 100, more than 1,000, more than 10,000, etc.).

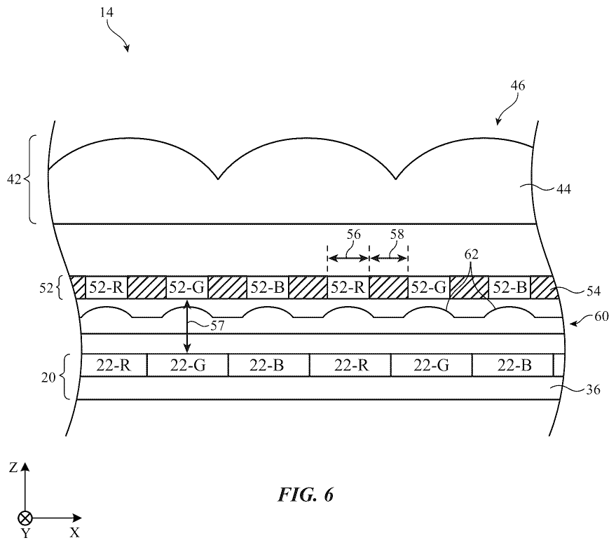

FIG. 6 is a cross-sectional side view of an illustrative display with a display panel 20 that has pixels 22 on a substrate 36. In FIG. 6, display panel 20 includes red pixels 22-R, green pixels 22-G, and blue pixels 22-B. The red pixels 22-R emit red light. The green pixels 22-G emit green light. The blue pixels 22-B emit blue light.

The display of FIG. 6 also includes lenticular lens film 42 over display panel 20. Lenticular lens film 42 includes lenses 46 and a base film portion 44 (e.g., a planar film portion to which lenses 46 are attached). Lenses 46 may be lenticular lenses that extend along respective longitudinal axes (e.g., axes that extend into the page parallel to the Y-axis).

Each pixel may emit light across an angular spread (sometimes referred to as a viewing angle, viewing cone, emission cone, etc.). If care is not taken, the angular spread may cause duplicate images (sometimes referred to as ghost images) to be visible when a user is viewing the display. To mitigate ghost images, it may be desirable to block light at large off-axis angles (e.g., at large angles relative to the Z-axis) while allowing light at on-axis angles (e.g., at angles parallel or close to parallel with the Z-axis) to pass to the viewer. Blocking off-axis light in this manner may mitigate ghost image artifacts in the display.

To mitigate artifacts, the display may therefore include a color filter layer 52 between lenticular lens film 42 and display panel 20. The color filter layer 52 includes a plurality of color filters. The color filters (sometimes referred to as color filter elements) include red color filters 52-R, green color filters 52-G, and blue color filters 52-B. Each color filter is aligned with a corresponding pixel of that color. In other words, each red color filter 52-R overlaps a corresponding red pixel 22-R in the Z-direction, each green color filter 52-G overlaps a corresponding green pixel 22-G in the Z-direction, and each blue color filter 52-B overlaps a corresponding blue pixel 22-B in the Z-direction. Each red color filter 52-R may transmit at least 90% of red light while blocking at least 90% of green and blue light. Each green color filter 52-G may transmit at least 90% of green light while blocking at least 90% of red and blue light. Each blue color filter 52-B may transmit at least 90% of blue light while blocking at least 90% of green and red light. The aforementioned magnitude of 90% is merely illustrative and other magnitudes may apply to the transmission and blocking of various colors of light by the color filters (e.g., at least 80%, at least 95%, etc.).

The color filter layer 52 may also include an opaque masking layer 54 that is formed between adjacent color filter elements. Opaque masking layer 54 may be formed by a dielectric material (e.g., a material that includes black ink) or other material that is substantially opaque to visible light. The transmission of visible light through opaque masking layer 54 may be less than 20%, less than 10%, less than 5%, etc.

The opaque masking layer 54 defines apertures (openings) that contain the color filters. Light is blocked by the opaque masking layer but passes through the apertures with the color filters. The color filter layer 52 (with opaque masking layer 54) may mitigate ghost image artifacts by passing on-axis light from the pixels while blocking off-axis light from the pixels.

Each color filter may have a width 56 within the XY-plane (e.g., parallel to the plane of the substrate). There is also a gap 58 between adjacent color filters that is filled by opaque masking layer 58. The magnitude of width 56 may be greater than 10 microns, greater than 20 microns, greater than 30 microns, greater than 50 microns, less than 100 microns, less than 50 microns, less than 30 microns, between 15 microns and 30 microns, etc. The magnitude of gap 58 may be greater than 10 microns, greater than 20 microns, greater than 30 microns, greater than 50 microns, less than 100 microns, less than 50 microns, less than 30 microns, between 15 microns and 30 microns, etc.

The magnitude of width 56 may be less than, greater than, or equal to the magnitude of gap 58. When the magnitude of width 56 is less than the magnitude of gap 58, the magnitude of 56 may be at least 5% less than the magnitude of gap 58, at least 10% less than the magnitude of gap 58, at least 20% less than the magnitude of gap 58, at least 50% less than the magnitude of gap 58, at least 75% less than the magnitude of gap 58, etc. When the magnitude of width 56 is greater than the magnitude of gap 58, the magnitude of 56 may be at least 5% greater than the magnitude of gap 58, at least 10% greater than the magnitude of gap 58, at least 20% greater than the magnitude of gap 58, at least 50% greater than the magnitude of gap 58, at least 75% greater than the magnitude of gap 58, etc.

To achieve the desired ghost image artifact reduction, the overall footprint (e.g., within the XY-plane) of color filter layer 52 occupied by the color filters may be relatively small. For example, the overall footprint of color filter layer 52 occupied by the color filters may be less than 75%, less than 50%, less than 35%, less than 30%, less than 25%, between 20% and 30%, between 20% and 50%, etc. The remaining percentage of the overall footprint of color filter layer 52 may be occupied by opaque masking layer 54. In other words, the overall footprint of color filter layer 52 occupied by the opaque masking layer 54 may be greater than 25%, greater than 50%, greater than 65%, greater than 70%, greater than 75%, between 70% and 80%, between 50% and 80%, etc.

There is a gap 57 (in the Z-direction/orthogonal to the plane of substrate 36) between pixels 22 and the color filters 52-R, 52-G, and 52-B. The magnitude of gap 57 may be greater than 3 microns, greater than 5 microns, greater than 10 microns, greater than 20 microns, greater than 30 microns, greater than 50 microns, less than 100 microns, less than 50 microns, less than 30 microns, less than 20 microns, between 15 microns and 50 microns, etc. The magnitude of gap 57 may be greater than the magnitude of width 56.

A gap (in the Z-direction/orthogonal to the plane of substrate 36) between pixels 22 and microlenses 62 may be greater than 3 microns, greater than 5 microns, greater than 10 microns, greater than 20 microns, greater than 30 microns, greater than 50 microns, less than 100 microns, less than 50 microns, less than 30 microns, less than 20 microns, between 15 microns and 50 microns, etc. The gap between pixels 22 and microlenses 62 may be greater than width 56.

Additional efficiency improvements may be achieved by incorporating a microlens layer 60 into display 14. The microlens layer 60 may include a plurality of microlenses 62. Each pixel 22 may be overlapped by a single respective microlens 62. The microlenses may collimate the light from pixels 22, thereby reducing the amount of off-axis light (that is blocked by color filter layer 52). The example of including microlens layer 60 in display 14 is merely illustrative and the microlens layer may optionally be omitted if desired.

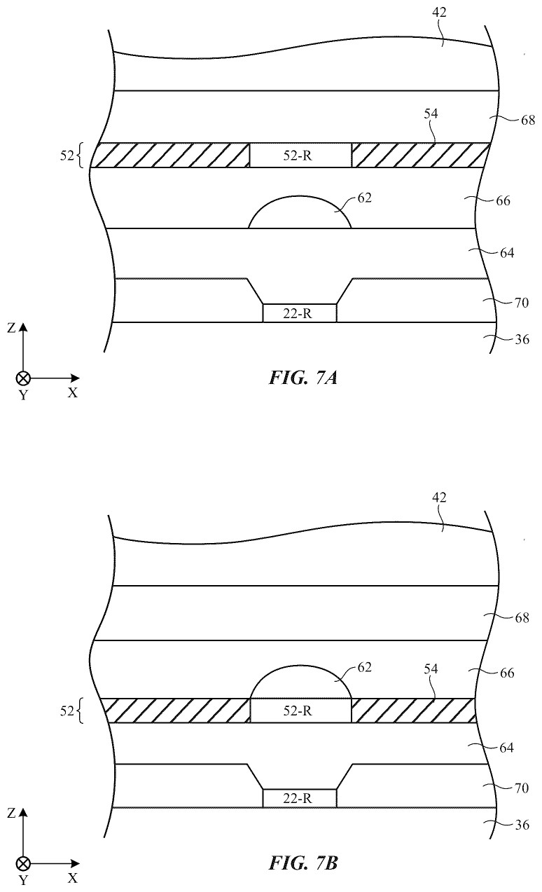

When display 14 includes microlenses 62, the microlenses may be incorporated either below color filter layer 52 (e.g., between color filter layer 52 and display panel 20) or above color filter layer 52 (e.g., between color filter layer 52 and lenticular lens film 42). FIG. 7A is a cross-sectional side view of a display with the microlenses positioned between color filter layer 52 and display panel 20. FIG. 7B is a cross-sectional side view of a display with the microlenses positioned between color filter layer 52 and lenticular lens film 42.

As shown in FIG. 7A, a pixel such as pixel 22-R may be formed on substrate 36. A dielectric layer 70 (sometimes referred to as a pixel definition layer) may be formed around pixel 22-R and define an aperture for pixel 22-R. Pixel 22-R may be a light-emitting diode pixel or other desired type of pixel. The pixel is covered by one more encapsulation layers 64. The encapsulation layers may include an organic material and/or an inorganic material. Encapsulation layer 64 may have a planar upper surface.

Microlenses 62 may be formed on the planar upper surface of encapsulation layer 64. One or more additional dielectric layers 66 (sometimes referred to as planarization layer 66) is formed over the microlens. Planarization layer 66 conforms to and directly contacts an upper surface of microlens 62. The material for microlens 62 may have a refractive index that is greater than 1.4, greater than 1.5, greater than 1.6, greater than 1.7, less than 1.8, less than 1.7, between 1.6 and 1.7, etc. The material for planarization layer 66 may have a refractive index that is less than 1.6, less than 1.5, less than 1.4, less than 1.3, greater than 1.2, greater than 1.3, between 1.3 and 1.4, etc. The difference in refractive indices between microlens 62 and planarization layer 66 may be greater than or equal to 0.1, greater than or equal to 0.2, greater than or equal to 0.3, etc.

Planarization layer 66 may have a planar upper surface. Color filter layer 52 is formed on the planar upper surface of planarization layer 66. An additional dielectric layer 68 may be formed over color filter layer 52 between color filter layer 52 and lenticular lens film 42. Lenticular lens film 42 may be filmed over and in direct contact with the planar upper surface of dielectric layer 68. In another possible arrangement, lenticular lens film 42 may be formed in direct contact with color filter layer 52.

The arrangement of FIG. 7B is similar to the arrangement of FIG. 7A and, in general, the properties described above in connection with FIG. 7A also apply to FIG. 7B. In FIG. 7B, encapsulation layer 64 and pixel definition layer 70 are formed over pixel 22-R (similar to as in FIG. 7A). However, in FIG. 7B, color filter layer 52 is formed on the planar upper surface of encapsulation layer 64. Microlens 62 is formed over and in direct contact with color filter 52-R. With this type of arrangement, each microlens in the microlens layer may be formed over and in direct contact with a respective color filter in color filter layer 52. Planarization layer 66 conforms to microlens 62 (similar to as in FIG. 7A). Additional dielectric layer 68 may be formed over planarization layer 66 between planarization layer 66 and lenticular lens film 42. Lenticular lens film 42 may be filmed over and in direct contact with the planar upper surface of dielectric layer 68. Dielectric layer 68 may optionally be omitted if desired. When dielectric layer 68 is omitted, lenticular lens film 42 may directly contact planarization layer 66.

The diameter of each microlens 62 may be equal to or similar to (e.g., within 5% of, within 10% of, within 20% of, etc.) the width 56 of the color filter with which it is aligned.

Including color filter layer 52 between the lenticular lenses and display pixels may mitigate reflections of ambient light off the display, improving contrast. The high ratio within the color filter layer of the surface area of opaque masking layer 54 to the surface area of the color filters causes a majority of ambient light to be absorbed by the opaque masking layer. Some ambient light may travel in the negative Z-direction and be absorbed by opaque masking layer 54 without passing through any of the color filters. Some ambient light may pass through a color filter in the negative Z-direction, reflect off the display panel, and then travel in the positive Z-direction where the light is absorbed by the opaque masking layer. Some ambient light may pass through a color filter of a first color in the negative Z-direction, reflect off the display panel, and then travel in the positive Z-direction where the light is absorbed by a color filter of a second color that is different than the first color. In all of the aforementioned paths, the ambient light is blocked from reflecting off of the display towards the viewer.

Some light may pass through a color filter of a first color in the negative Z-direction, reflect off the display panel, and then pass through a color filter of the first color in the positive Z-direction towards a viewer. However, with the arrangement of FIG. 6, a relatively small amount (e.g., less than 10%, less than 5%, less than 4%, between 2% and 6%, etc.) of ambient light may reflect off of the display towards the viewer.

The mitigation of ambient light reflections by color filter layer 52 may be sufficiently high to omit a separate circular polarizer that may otherwise be used in display 14 for ambient light reflection mitigation. The electronic device 10 (and display 14) may have no circular polarizer that overlaps pixels 22 in the positive Z-direction. Display 14 may sometimes be referred to as a polarizer-free display.

FIG. 6 shows an example where display 14 is planar. However, in some electronic devices, it may be desirable for display 14 to be curved. Curving display 14 may allow the display to conform to a desired form factor for the electronic device 10, may provide a desired aesthetic appearance, etc. The display may have concave curvature or convex curvature.

Providing curvature in a lenticular display may impact the performance of the lenticular display. In particular, the curvature of the display means that the angle of the surface of the display relative to the viewer is not constant. This may make it difficult for all of the pixels in the lenticular display to be properly viewable.

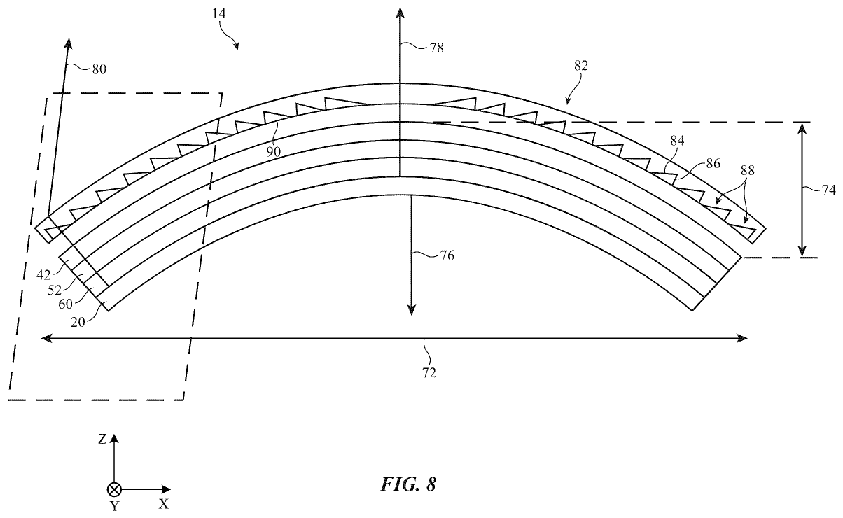

As shown in FIG. 8, lenticular display 14 may have convex curvature. The display panel may have first and second opposing surfaces. The first surface has concave curvature and the second surface as convex curvature. The display panel emits light from the second (convex curved) surface in the positive Z-direction (away from the first, concave curved surface).

As shown in FIG. 8, display 14 may have a width 72, height 74, and radius of curvature 76. Width 72 may refer to the width of the footprint of display 14 (e.g., the width of the outline of the display when viewed from above, not accounting for the display's curvature). Width 72 may sometimes be referred to as a footprint width. Display 14 may also have a panel width that refers to the width of display 14 before bending occurs. Height 74 may refer to the vertical distance (e.g., along the Z-axis) between the upper-most portion of the lenticular lenses of the display (e.g., at the center of the display) and the lower-most portion of the lenticular lenses of the display (e.g., at the left and right edges of the display).

In FIG. 8, width 72 may be between 100 and 200 millimeters, greater than 60 millimeters, greater than 100 millimeters, greater than 150 millimeters, greater than 200 millimeters, greater than 500 millimeters, greater than 1,000 millimeters, less than 300 millimeters, less than 200 millimeters, between 125 and 175 millimeters etc. Height 74 may be greater than 1 millimeter, greater than 2 millimeters, greater than 4 millimeters, greater than 5 millimeters, greater than 10 millimeters, greater than 15 millimeters, greater than 20 millimeters, greater than 100 millimeters, between 5 and 10 millimeters, between 10 and 15 millimeters, between 11 and 13 millimeters, less than 10 millimeters, etc. In one illustrative arrangement, display 14 has a width 72 of approximately (e.g., within 10% of) 150 millimeters and a height 74 of approximately (e.g., within 10% of) 12 millimeters.

The curvature of the display in FIG. 8 may also be characterized by radius of curvature 76. The radius of curvature refers to the radius of the circular arc that best approximates the curve at that point. Therefore, a large radius of curvature indicates a mild curvature (because the curve develops over a longer distance) whereas a small radius of curvature indicates tight curvature (because the curve develops over a shorter distance). In FIG. 8, the radius of curvature is uniform across the display. The radius of curvature may be approximately (e.g., within 10% of) 290 millimeters. This example is merely illustrative, and the radius of curvature may be lower or higher if desired (e.g., greater than 200 millimeters, greater than 400 millimeters, greater than 600 millimeters, greater than 800 millimeters, greater than 1,000 millimeters, less than 800 millimeters, less than 500 millimeters, less than 400 millimeters, less than 300 millimeters, less than 200 millimeters, between 250 and 350 millimeters, etc.).

When display 14 has convex curvature, pixels in a center of the display may emit light 78 that is parallel to the Z-axis. However, the pixels may emit light with an increasing angle relative to the Z-axis with increasing separation from the center of the display along the X-direction. At an edge of the display, the pixels may emit light 80 that is initially at an angle relative to the Z-axis. The angle may be greater than 3 degrees, greater than 5 degrees, greater than 10 degrees, greater than 20 degrees, greater than 30 degrees, etc. If care is not taken, the light from the edge of the convex curved display may not be visible to a viewer that is centered with the display and looking in the negative Z-direction.

To redirect the light from the edge of the display towards a viewer, display 14 may also include a Fresnel lens layer 82. Fresnel lens layer 82 is characterized by slope facets 84 and draft facets 86. Facets 84 and 86 are formed from the surfaces of Fresnel lens portions 88. Each Fresnel lens portion 88 may extend in a strip parallel to the direction of the lenticular lenses (e.g., in the Y-direction). There may be any suitable number of Fresnel lens portions 88 in Fresnel lens 82 (e.g., 50, 10-100, at least 5, at least 10, at least 15, at least 20, at least 30, at least 45, at least 75, fewer than 200, fewer than 150, or other suitable number). Slope facets 84 have a curved lens-shaped profile at angles (e.g., less than 45°, less than 30°, less than 20°, 0-20°, 0-30°, 0-40°, at least 2°, etc.) with respect to the lower surface 90 of the Fresnel lens layer. Draft facets 86, which may have straight cross-sectional profiles, typically have relatively small angles (e.g., 2°) with respect to the surface normal of the Fresnel lens layer at that point. Because of these orientations, draft facets 86 may sometimes be referred to as vertically extending facets and slope facets 84 may sometimes be referred to as horizontally extending or laterally extending facets. Fresnel lens layer portions 88 may be formed from glass or plastic, as examples. The Fresnel lens portions 88 may optionally be overlapped by an encapsulation layer. In another possible arrangement, the Fresnel lens portions may be formed as recesses in a transparent layer (e.g., formed from glass or plastic).

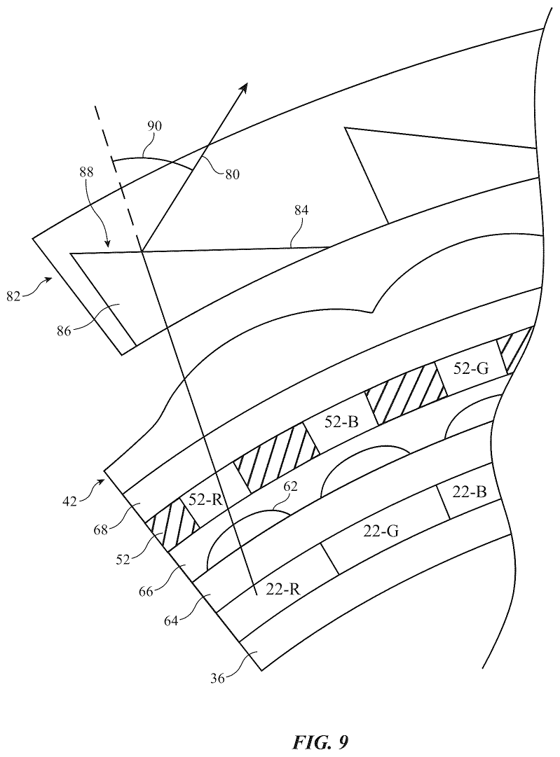

FIG. 9 is a zoomed in view of the lenticular display 14 with a Fresnel lens layer 82. As shown, light 80 is emitted from pixel 22-R in a first direction. Fresnel lens portion 88 (and in particular the slope facet 84) redirect the light by angle 90. Angle 90 may sometimes be referred to as a deflection angle. The deflection angle caused by Fresnel lens layer 82 may be larger at the edge of the display than at the center of the display. The deflection angle caused by Fresnel lens layer 82 may gradually decrease from the edge of the display towards the center of the display.

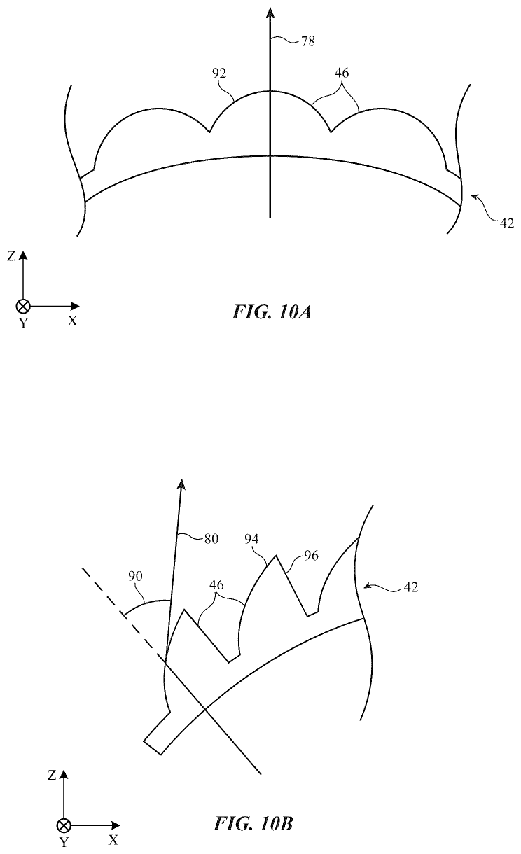

Another option for redirecting light at different angles at different positions across the lenticular display is using lenticular lenses with different shapes at different positions along the X-direction. FIGS. 10A and 10B show an example of this type. FIG. 10A shows the center of a lenticular lens film (e.g., a portion of the lenticular lens film that overlaps the center of the lenticular display). FIG. 10B shows the edge of the lenticular lens film of FIG. 10A (e.g., a portion of the lenticular lens film that overlaps the edge of the lenticular display).

As shown in FIG. 10A, at the center of the lenticular lens film at least one lenticular lens may have a symmetrical shape (along the X-direction). The lenticular lens with the symmetrical shape may pass light 78 parallel to the Z-direction towards a viewer (with no substantial deflection of the light).

In contrast, as shown in FIG. 10B, at the edge of the lenticular lens film the lenticular lenses may have an asymmetrical shape (along the X-direction). Each asymmetrical lenticular lens may deflect light by a respective angle 90. The magnitude of angle 90 may be tuned to redirect light such as light 80 towards a viewer in the positive Z-direction.

The symmetric lenticular lens in the center of the lens film may have a curved upper surface 92. In contrast, the asymmetric lenticular lens at the edge of the lens film may have a curved upper surface 94 that meets a planar side surface 96.

The lens shape may progressively shift from a symmetric shape at the center of the display to an asymmetric shape at the edge of the display. The amount of asymmetry in each lenticular lens shape may increase continuously and monotonically from the center to the edge or may increase according to a step function. There may be at least two different lens shapes present in the display, at least three different lens shapes present in the display, at least five different lens shapes present in the display, at least ten different lens shapes present in the display, etc. The lenticular lens shapes may be shifted such that light from the display is emitted in an on-axis direction after the display is curved.

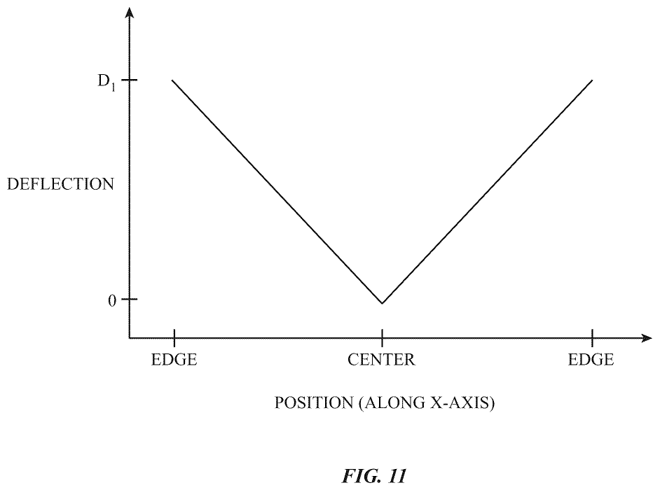

FIG. 11 is a graph of deflection angle as a function of position for the Fresnel lens layer of FIGS. 8 and 9 and the lenticular lens film (with different lens shapes) of FIGS. 10A and 10B. The deflection angle refers to angle 90 in FIGS. 9 and 10B. The position refers to the position on the display along the X-axis. As shown, the deflection provided by the Fresnel lens layer (in the embodiment of FIGS. 8 and 9) and lenticular lens film 42 (in the embodiment of FIGS. 10A and 10B) is at a minimum (e.g., 0) in a center of the display. Because the light in the center of the display is already emitted in the positive Z-direction, no deflection of this light is necessary. The deflection provided by the Fresnel lens layer and lenticular lens film 42 is at a maximum (D1) at each edge of the display. Between each edge and center of the display, the deflection gradually decreases from the maximum (D1) to the minimum (0). FIG. 11 shows a linear profile for the change in deflection between the center and edge of the display. This example is merely illustrative and the profile may instead be non-linear if desired. In general, the profile for the change in deflection between the center and edge of the display may be selected to cause the deflected light across the entire display to travel approximately (e.g., within 10 degrees of, within 5 degrees of, within 3 degrees of, within 1 degree of, etc.) in the positive Z-direction.

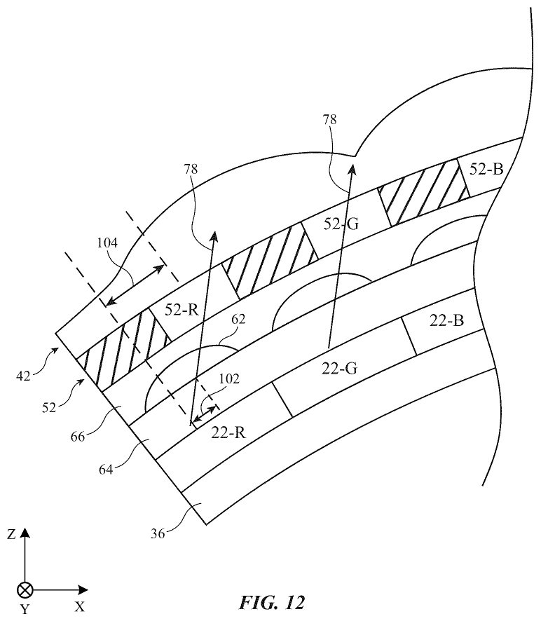

FIG. 12 shows a lenticular display with convex curvature and lateral shifts between the color filters, microlenses, and pixels to cause light to be emitted in the positive Z-direction across the display (even when no Fresnel lens layer is included and the lenticular lens shapes are constant across the display). As shown in FIG. 12, the center of microlens 62 may be shifted by distance 102 relative to the center of pixel 22-R within the plane defined by substrate 36 at the substrate position on which the pixel is formed. Similarly, the center of color filter 52-R may be shifted by distance 104 relative to the center of pixel 22-R within the plane defined by substrate 36 at the substrate position on which the pixel is formed.

Shifts 102 and 104 may be towards the center of the lenticular display. Shift 104 may be greater than shift 102. This arrangement causes light from the pixels at the edge of the display to pass in direction 78 parallel to the Z-axis.

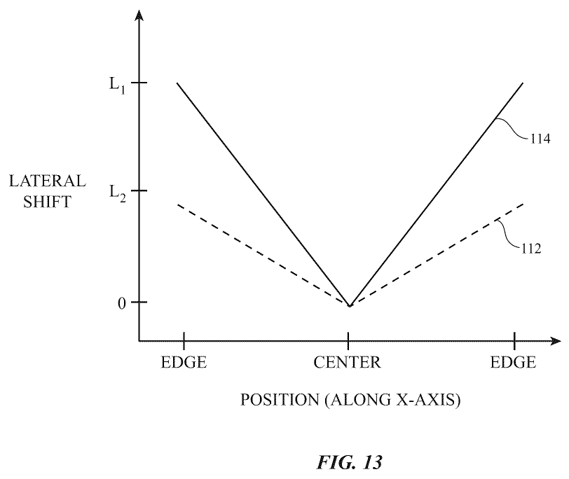

FIG. 13 is a graph of lateral shift as a function of position across the display. Profile 114 in FIG. 13 shows the magnitude of shift 104 across the display and profile 112 in FIG. 13 shows the magnitude of shift 102 across the display. In FIG. 13, position refers to the position on the display along the X-axis.

As shown, for both profiles 114 and 112 the shift is at a minimum (e.g., 0) in a center of the display. Because the light in the center of the display is already emitted in the positive Z-direction, no lateral shift is necessary at this position. For each of profiles 112 and 114, the lateral shift is at a maximum at each edge of the display. The maximum lateral shift for shift 102 is L₂ whereas the maximum lateral shift for shift 104 is L₁. L₁ is greater than L₂. Between the edge and center of the display, the lateral shift gradually decreases from the maximum to the minimum (0). FIG. 13 shows linear profiles for the change in lateral shift between the center and edge of the display. This example is merely illustrative and the profiles may instead be non-linear if desired. In general, the profiles for the change in lateral shift between the center and edge of the display may be selected to cause the light across the entire display to travel approximately (e.g., within 10 degrees of, within 5 degrees of, within 3 degrees of, within 1 degree of, etc.) in the positive Z-direction.

It should be understood that the paths of light shown herein may reflect the center of a cone of light that has a corresponding angular spread.

The foregoing is merely illustrative and various modifications can be made to the described embodiments. The foregoing embodiments may be implemented individually or in any combination.

1. An electronic device that includes a display, the display comprising:
a substrate;
an array of pixels formed on the substrate, wherein the array of pixels comprises red pixels, green pixels, and blue pixels;
a lenticular lens film formed over the array of pixels; and
a color filter layer that is interposed between the array of pixels and the lenticular lens film, wherein the color filter layer comprises an opaque masking layer that defines openings for color filters and wherein the color filters comprise red color filters that are aligned with the red pixels, green color filters that are aligned with the green pixels, and blue color filters that are aligned with the blue pixels.

2. The electronic device defined in claim 1, wherein the color filters have a width, wherein adjacent color filters are separated by a gap that is filled by the opaque masking layer, and wherein a magnitude of the width is less than a magnitude of the gap.

3. The electronic device defined in claim 1, wherein the color filters have a width, wherein the color filter layer is separated from the array of pixels by a gap, and wherein a magnitude of the width is less than a magnitude of the gap.

4. The electronic device defined in claim 1, further comprising:
microlenses that are interposed between the lenticular lens film and the array of pixels, wherein each pixel of the array of pixels is aligned with a respective microlens of the microlenses.

5. The electronic device defined in claim 4, wherein the microlenses are interposed between the color filter layer and the lenticular lens film.

6. The electronic device defined in claim 4, wherein the microlenses are interposed between the color filter layer and the array of pixels.

7. The electronic device defined in claim 4, wherein the microlenses have a first refractive index, wherein the microlenses are covered by a planarization layer that has a second refractive index, and wherein a difference between the first refractive index and the second refractive index is greater than or equal to 0.2.

8. The electronic device defined in claim 7, wherein the second refractive index is greater than the first refractive index.

9. The electronic device defined in claim 1, wherein the lenticular lens film comprises lenticular lenses that are elongated in a first direction.

10. The electronic device defined in claim 9, wherein the lenticular lenses are curved along a second direction that is orthogonal to the first direction and wherein the lenticular lenses spread light from the array of pixels in the second direction.

11. The electronic device defined in claim 1, wherein the substrate has first and second opposing surfaces, wherein the first surface is interposed between the array of pixels and the second surface, and wherein the first surface has convex curvature.

12. The electronic device defined in claim 11, wherein the display further comprises:
a Fresnel lens layer, wherein the lenticular lens film is interposed between the color filter layer and the Fresnel lens layer.

13. The electronic device defined in claim 12, wherein the Fresnel lens layer is configured to redirect light by a first magnitude at a center of the display and wherein the Fresnel lens layer is configured to redirect light by a second magnitude that is greater than the first magnitude at an edge of the display.

14. The electronic device defined in claim 11, wherein the lenticular lens film comprises at least first and second lenticular lenses, wherein the first lenticular lens is formed at a center of the display and has a first shape, and wherein the second lenticular lens is formed at an edge of the display and has a second shape that is different than the first shape.

15. The electronic device defined in claim 14, wherein the first shape is symmetric and wherein the second shape is asymmetric.

16. The electronic device defined in claim 14, wherein the second lenticular lens is configured to redirect light by a greater amount than the first lenticular lens.

17. The electronic device defined in claim 1, wherein, at an edge of the display, each color filter is shifted, parallel to a plane defined by the substrate, towards a center of the display relative to a pixel that is aligned with that color filter.

18. An electronic device that includes a display, the display comprising:
a substrate having first and second opposing surfaces, wherein the first surface has convex curvature;
an array of pixels that conforms to the first surface and has the convex curvature;
a lenticular lens film formed over the array of pixels;
a color filter layer that is interposed between the array of pixels and the lenticular lens film, wherein the color filter layer comprises color filters and an opaque masking layer between the color filters; and
a Fresnel lens layer that is formed over the lenticular lens film, wherein the Fresnel lens layer redirects light from the array of pixels by different amounts at different positions across the display.

19. The electronic device defined in claim 18, wherein the Fresnel lens layer redirects light from the array of pixels by a first amount at a center of the display and by a second amount that is greater than the first amount at an edge of the display.

20. An electronic device that includes a display, the display comprising:
a substrate having first and second opposing surfaces, wherein the first surface has convex curvature;
an array of pixels that conforms to the first surface and has the convex curvature;
a lenticular lens film formed over the array of pixels; and
a color filter layer that is interposed between the array of pixels and the lenticular lens film, wherein the color filter layer comprises color filters and an opaque masking layer between the color filters, a first color filter in a center of the display overlaps a first pixel in a first direction, a second color filter in an edge the display overlaps a second pixel in the first direction, the first color filter has a first center, the first pixel has a second center, the second color filter has a third center, the second pixel has a fourth center, the first center is aligned with the second center in the first direction, and the third center is shifted relative to the fourth center in a direction that is parallel to a plane defined by the substrate at a portion of the substrate that supports the second pixel.
